(19) United States
(12) Patent Application Publication
(10) Pub. No.: US 2025/0357348 A1
(43) Pub. Date: Nov. 20, 2025

(54) BARRIER FREE TUNGSTEN LINER IN CONTACT PLUGS AND THE METHOD FORMING THE SAME

(71) Applicant: Taiwan Semiconductor Manufacturing Co., Ltd., Hsinchu (TW)

(72) Inventors: Feng-Yu Chang, Kaohsiung City (TW); Sheng-Hsuan Lin, Zhubei City (TW); Shu-Lan Chang, Hsinchu (TW); Kai-Yi Chu, Hsinchu (TW); Meng-Hsien Lin, Taichung City (TW); Pei-Hsuan Lee, Taipei City (TW); Pei Shan Chang, Taipei City (TW); Chih-Chien Chi, Hsinchu (TW); Chun-I Tsai, Hsinchu (TW); Wei-Jung Lin, Hsinchu (TW); Chih-Wei Chang, Hsinchu (TW); Ming-Hsing Tsai, Chu-Pei City (TW); Syun-Ming Jang, Hsinchu (TW); Wei-Jen Lo, Hsinchu (TW)

(21) Appl. No.: 19/286,574

(22) Filed: Jul. 31, 2025

Related U.S. Application Data
(63) Continuation of application No. 18/345,303, filed on Jun. 30, 2023.
(60) Provisional application No. 63/497,478, filed on Apr. 21, 2023.

(51) Int. Cl. H01L 23/532; H01L 21/768; H10D 30/01; H10D 30/62; H10D 84/01; H10D 84/03; H10D 84/83

(52) U.S. Cl. CPC H01L 23/53266; H01L 21/7684; H01L 21/76876; H01L 21/76877; H01L 21/76897; H10D 30/024; H10D 30/62; H10D 30/6219; H10D 84/0158; H10D 84/038; H10D 84/834

(57) ABSTRACT

A method includes forming a dielectric layer over a conductive feature, and etching the dielectric layer to form an opening. The conductive feature is exposed through the opening. The method further includes forming a tungsten liner in the opening, wherein the tungsten liner contacts sidewalls of the dielectric layer, depositing a tungsten layer to fill the opening, and planarizing the tungsten layer. Portions of the tungsten layer and the tungsten liner in the opening form a contact plug.

### PRIORITY CLAIM AND CROSS-REFERENCE

This application is a continuation of U.S. patent application Ser. No. 18/345,303, filed on Jun. 30, 2023 and entitled “BARRIER FREE TUNGSTEN LINER IN CONTACT PLUGS AND THE METHOD FORMING THE SAME,” which application claims the benefit of the following provisionally filed U.S. Patent application: Application No. 63/497,478, filed on Apr. 21, 2023, and entitled “Barrier Free W-liner for Low-R and Low-Cost Plug,” which applications are hereby incorporated herein by reference.

### BACKGROUND

In the manufacturing of integrated circuits, source/drain contact plugs are used for connecting to the source and drain regions of transistors. The source/drain contact plugs are typically connected to source/drain silicide regions. The formation of the source/drain contact plugs includes forming contact openings in an inter-layer dielectric, depositing a metal layer extending into the contact openings, and then performing an anneal process to react the metal layer with the silicon/germanium of the source/drain regions. The source/drain contact plugs are then formed in the remaining contact openings. The gate contact plugs are also formed to connect to the gates of the transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7, 8A, 8B, 9-22, 23A, 23B, 23C, and 24 illustrate the views of intermediate stages in the formation of Fin Field-Effect Transistors (FinFETs) in accordance with some embodiments.

FIGS. 25 and 26 illustrate the top views of some structures that can adopt the contact plugs in accordance with the embodiments of the present disclosure.

FIG. 27 illustrates an example distribution profile of fluorine and boron in accordance with some embodiments.

FIG. 28 illustrates a process flow for forming FinFETs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Transistors and contact plugs are provided in accordance with various embodiments. The corresponding formation processes are also provided. In accordance with some embodiments, the contact plugs include tungsten liners and additional tungsten layers over the tungsten liners. The tungsten liners may be formed using Physical Vapor Deposition (PVD). By adopting tungsten liners, the contact resistance may be reduced, and is lower than that of the contact plugs adopting Ti/TiN liners. Seams may also be reduced or eliminated. Some variations of some embodiments are discussed. Throughout the various views and illustrative embodiments, like reference numbers are used to designate like elements. In accordance with some embodiments, the formation of Fin Field-Effect Transistors (FinFETs) is used as an example to explain the concept of the present disclosure. Other types of transistors such as planar transistors, Gate-All-Around (GAA) transistors, Complementary Field-Effect Transistors (CFETs), and the corresponding contact plugs may also adopt the concept of the present disclosure.

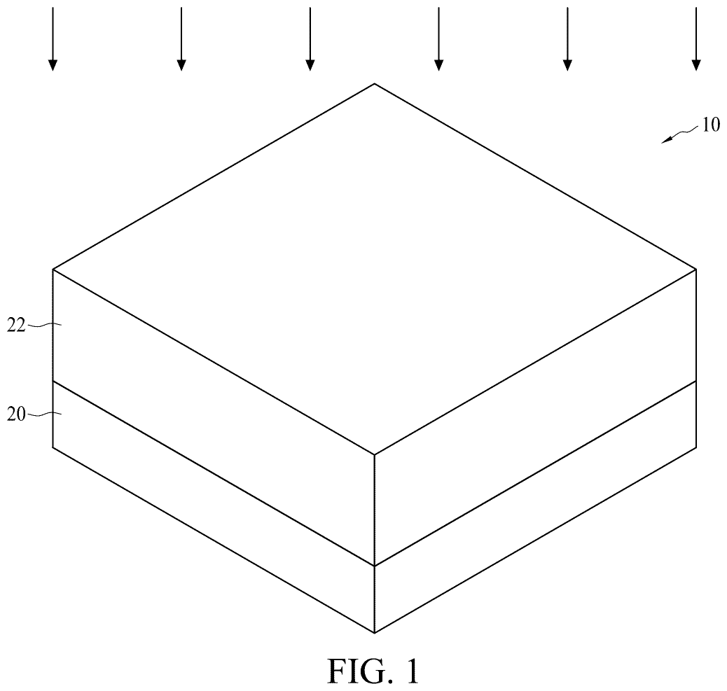

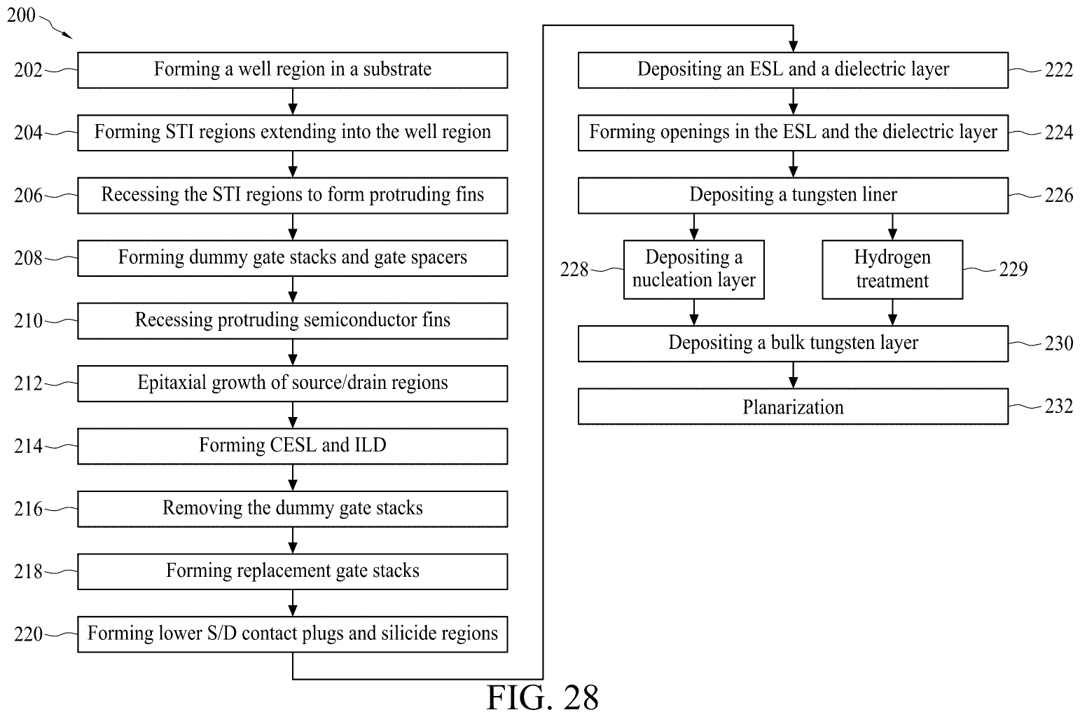

FIGS. 1-7, 8A, 8B, 9-22, 23A, 23B, 23C, and 24 illustrate the views of intermediate stages in the formation of Fin Field-Effect Transistors (FinFETs) and contact plugs in accordance with some embodiments. The processes shown in these figures are also reflected schematically in the process flow 200 as shown in FIG. 28.

In FIG. 1, substrate 20 is provided. The substrate 20 may be a semiconductor substrate, such as a bulk semiconductor substrate, a Semiconductor-On-Insulator (SOI) substrate, or the like, which may be doped (e.g., with a p-type or an n-type dopant) or undoped. The semiconductor substrate 20 may be a part of wafer 10, such as a silicon wafer. Generally, an SOI substrate is a layer of a semiconductor material formed on an insulator layer. The insulator layer may be, for example, a Buried Oxide (BOX) layer, a silicon oxide layer, or the like. The insulator layer is provided on a substrate, typically a silicon substrate or a glass substrate. Other substrates such as a multi-layered or gradient substrate may also be used.

In some embodiments, the semiconductor material of semiconductor substrate 20 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Further referring to FIG. 1, well region 22 is formed in substrate 20. The respective process is illustrated as process 202 in the process flow 200 as shown in FIG. 28. In accordance with some embodiments, well region 22 is an n-type well region formed through implanting an n-type impurity, which may be phosphorus, arsenic, antimony, or the like, into substrate 20. In accordance with other embodiments of the present disclosure, well region 22 is a p-type well region formed through implanting a p-type impurity, which may be boron, indium, or the like, into substrate 20. The resulting well region 22 may extend to the top surface of substrate 20. The n-type or p-type impurity concentration may be equal to or less than 10¹⁸ cm⁻³, such as in the range between about 10¹⁷ cm⁻³ and about 10¹⁸ cm⁻³.

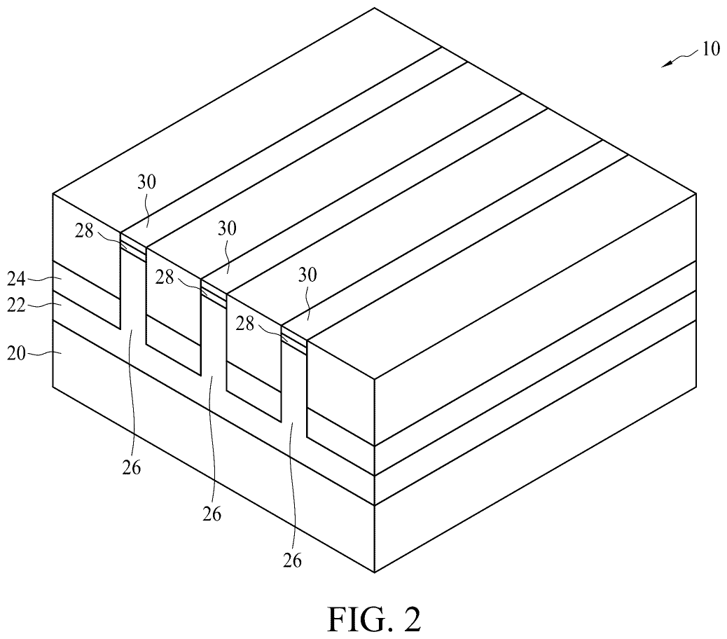

Referring to FIG. 2, isolation regions 24 are formed to extend from a top surface of substrate 20 into substrate 20. Isolation regions 24 are alternatively referred to as Shallow Trench Isolation (STI) regions hereinafter. The respective process is illustrated as process 204 in the process flow 200 as shown in FIG. 28. The portions of substrate 20 between neighboring STI regions 24 are referred to as semiconductor strips 26. To form STI regions 24, pad oxide layer 28 and hard mask layer 30 are formed on semiconductor substrate 20, and are then patterned. Pad oxide layer 28 may be a thin film formed of silicon oxide. In accordance with some embodiments, pad oxide layer 28 is formed in a thermal oxidation process, wherein a top surface layer of semiconductor substrate 20 is oxidized. Pad oxide layer 28 acts as an adhesion layer between semiconductor substrate 20 and hard mask layer 30. Pad oxide layer 28 may also act as an etch stop layer for etching hard mask layer 30.

In accordance with some embodiments, hard mask layer 30 is formed of silicon nitride, for example, using Low-Pressure Chemical Vapor Deposition (LPCVD). In accordance with other embodiments of the present disclosure, hard mask layer 30 is formed by thermal nitridation of silicon, or Plasma Enhanced Chemical Vapor Deposition (PECVD). A photo resist (not shown) is formed on hard mask layer 30 and is then patterned. Hard mask layer 30 is then patterned using the patterned photo resist as an etching mask to form hard masks 30 as shown in FIG. 2.

Next, the patterned hard mask layer 30 is used as an etching mask to etch pad oxide layer 28 and substrate 20, followed by filling the resulting trenches in substrate 20 with a dielectric material(s). A planarization process such as a Chemical Mechanical Polish (CMP) process or a mechanical grinding process is performed to remove excess portions of the dielectric materials, and the remaining portions of the dielectric materials(s) are STI regions 24. STI regions 24 may include a liner dielectric (not shown), which may be a thermal oxide formed through a thermal oxidation of a surface layer of substrate 20. The liner dielectric may also be a deposited silicon oxide layer, silicon nitride layer, or the like formed using, for example, Atomic Layer Deposition (ALD), High-Density Plasma Chemical Vapor Deposition (HDPCVD), or Chemical Vapor Deposition (CVD). STI regions 24 may also include a dielectric material over the liner oxide, wherein the dielectric material may be formed using Flowable Chemical Vapor Deposition (FCVD), spin-on coating, or the like. The dielectric material over the liner dielectric may include silicon oxide in accordance with some embodiments.

The top surfaces of hard masks 30 and the top surfaces of STI regions 24 may be substantially level with each other. Semiconductor strips 26 are between neighboring STI regions 24. In accordance with some embodiments, semiconductor strips 26 are parts of the original substrate 20, and hence the material of semiconductor strips 26 is the same as that of substrate 20. In accordance with alternative embodiments of the present disclosure, semiconductor strips 26 are replacement strips formed by etching the portions of substrate 20 between STI regions 24 to form recesses, and performing an epitaxy to regrow another semiconductor material in the recesses. Accordingly, semiconductor strips 26 are formed of a semiconductor material different from that of substrate 20. In accordance with some embodiments, semiconductor strips 26 are formed of silicon germanium, silicon carbon, or a III-V compound semiconductor material.

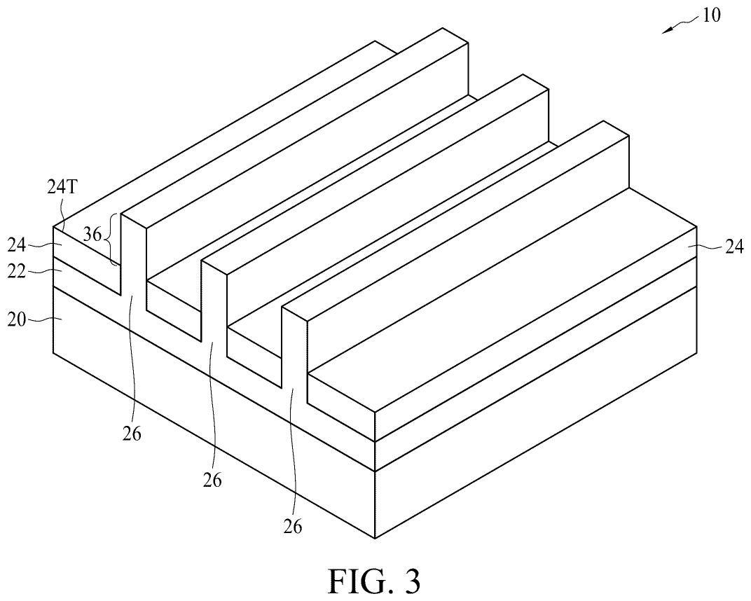

Referring to FIG. 3, STI regions 24 are recessed, so that the top portions of semiconductor strips 26 protrude higher than the top surfaces 24T of the remaining portions of STI regions 24 to form protruding fins 36. The respective process is illustrated as process 206 in the process flow 200 as shown in FIG. 28. The etching may be performed using a dry etching process, wherein HF₃ and NH₃, for example, are used as the etching gases. During the etching process, plasma may be generated. Argon may also be included. In accordance with alternative embodiments of the present disclosure, the recessing of STI regions 24 is performed using a wet etch process. The etching chemical may include HF, for example.

In above-illustrated embodiments, the fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins.

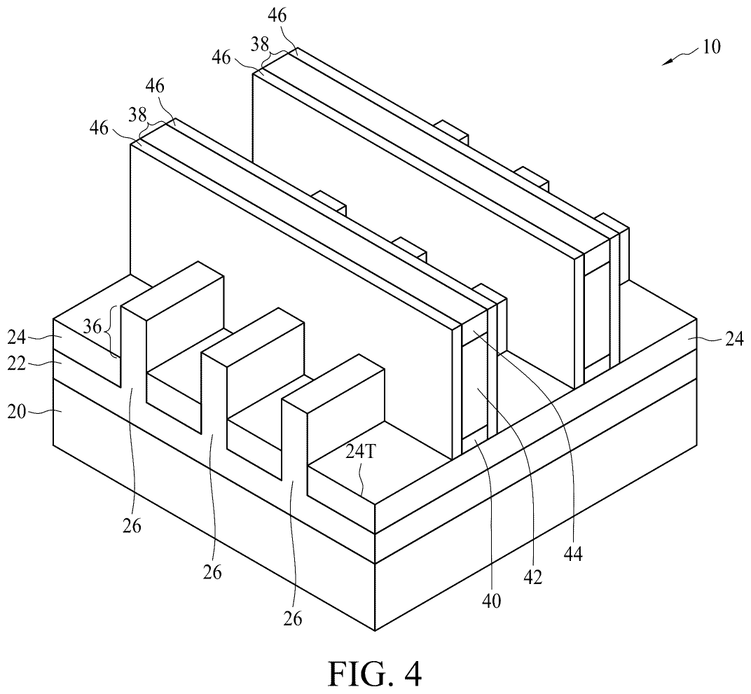

Referring to FIG. 4, dummy gate stacks 38 are formed to extend on the top surfaces and the sidewalls of (protruding) fins 36. The respective process is illustrated as process 208 in the process flow 200 as shown in FIG. 28. Dummy gate stacks 38 may include dummy gate dielectrics 40 and dummy gate electrodes 42 over dummy gate dielectrics 40. Dummy gate electrodes 42 may be formed, for example, using polysilicon, and other materials may also be used. Each of dummy gate stacks 38 may also include one (or a plurality of) hard mask layer 44 over dummy gate electrodes 42. Hard mask layers 44 may be formed of silicon nitride, silicon oxide, silicon carbo-nitride, or multi-layers thereof. Dummy gate stacks 38 may cross over a single one or a plurality of protruding fins 36 and/or STI regions 24. Dummy gate stacks 38 also have lengthwise directions perpendicular to the lengthwise directions of protruding fins 36.

Next, gate spacers 46 are formed on the sidewalls of dummy gate stacks 38. The respective process is also shown as process 208 in the process flow 200 as shown in FIG. 28. In accordance with some embodiments, gate spacers 46 are formed of a dielectric material(s) such as silicon nitride, silicon carbo-nitride, or the like, and may have a single-layer structure or a multi-layer structure including a plurality of dielectric layers.

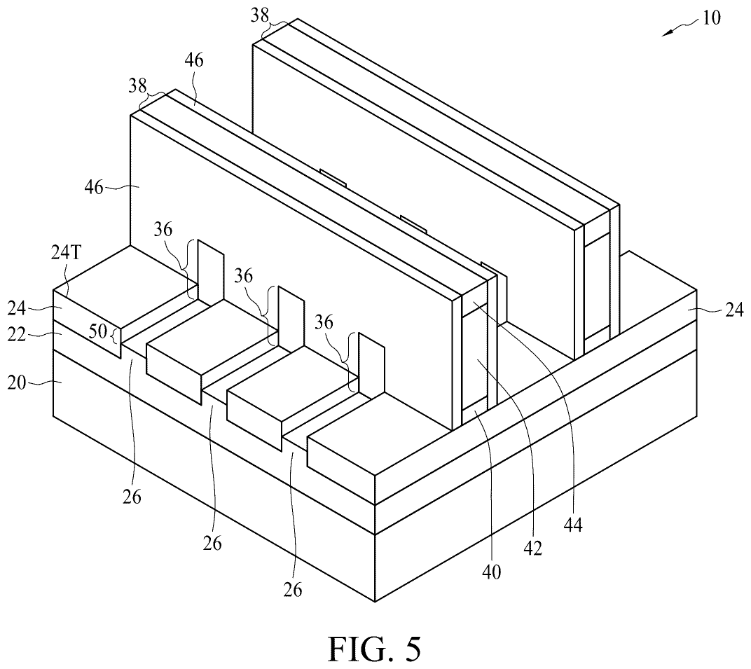

An etching process is then performed to etch the portions of protruding fins 36 that are not covered by dummy gate stacks 38 and gate spacers 46, resulting in the structure shown in FIG. 5. The respective process is illustrated as process 210 in the process flow 200 as shown in FIG. 28. The recessing may be anisotropic, and hence the portions of fins 36 directly underlying dummy gate stacks 38 and gate spacers 46 are protected, and are not etched. The top surfaces of the recessed semiconductor strips 26 may be lower than the top surfaces 24T of STI regions 24 in accordance with some embodiments. The spaces left by the etched protruding fins 36 are referred to as recesses 50. Recesses 50 comprise portions located between neighboring gate stack 38. Some lower portions of recesses 50 are between neighboring STI regions 24.

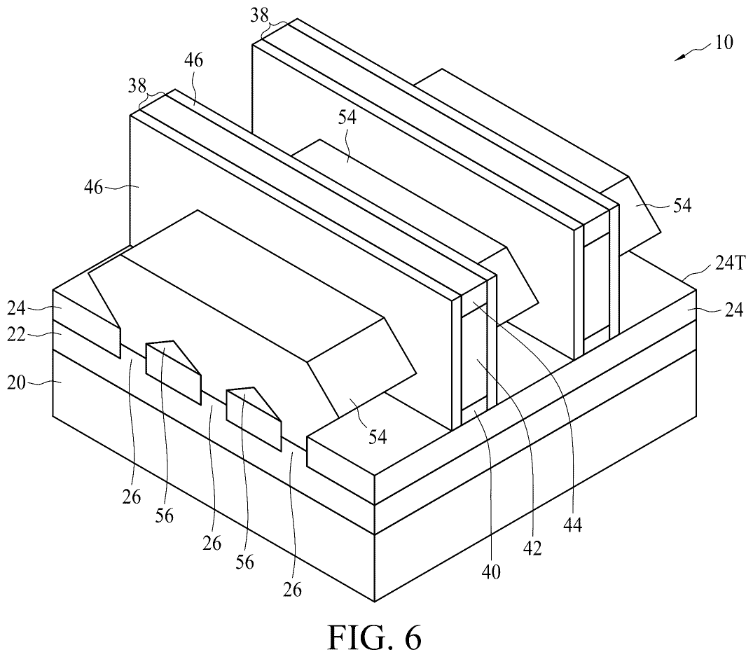

Next, epitaxy regions (source/drain regions) 54 are formed by selectively growing (through epitaxy) a semiconductor material in recesses 50, resulting in the structure in FIG. 6. The respective process is illustrated as process 212 in the process flow 200 as shown in FIG. 28. Source/drain region(s) may refer to a source or a drain, individually or collectively dependent upon the context. Depending on whether the resulting FinFET is a p-type FinFET or an n-type FinFET, a p-type or an n-type impurity may be in-situ doped with the proceeding of the epitaxy. For example, when the resulting FinFET is a p-type FinFET, silicon germanium boron (SiGeB), silicon boron (SiB), or the like may be grown. Conversely, when the resulting FinFET is an n-type FinFET, silicon phosphorous (SiP), silicon carbon phosphorous (SiCP), or the like may be grown. In accordance with alternative embodiments of the present disclosure, epitaxy regions 54 comprise III-V compound semiconductors such as GaAs, InP, GaN, InGaAs, InAlAs, GaSb, AlSb, AlAs, AlP, GaP, combinations thereof, or multi-layers thereof. After Recesses 50 are filled with epitaxy regions 54, the further epitaxial growth of epitaxy regions 54 causes epitaxy regions 54 to expand horizontally, and facets may be formed. The further growth of epitaxy regions 54 may also cause neighboring epitaxy regions 54 to merge with each other. Voids (air gaps) 56 may be generated.

After the epitaxy step, epitaxy regions 54 may be further implanted with a p-type or an n-type impurity to form source and drain regions, which are also denoted using reference numeral 54. In accordance with alternative embodiments of the present disclosure, the implantation process is skipped when epitaxy regions 54 are in-situ doped with the p-type or n-type impurity during the epitaxy.

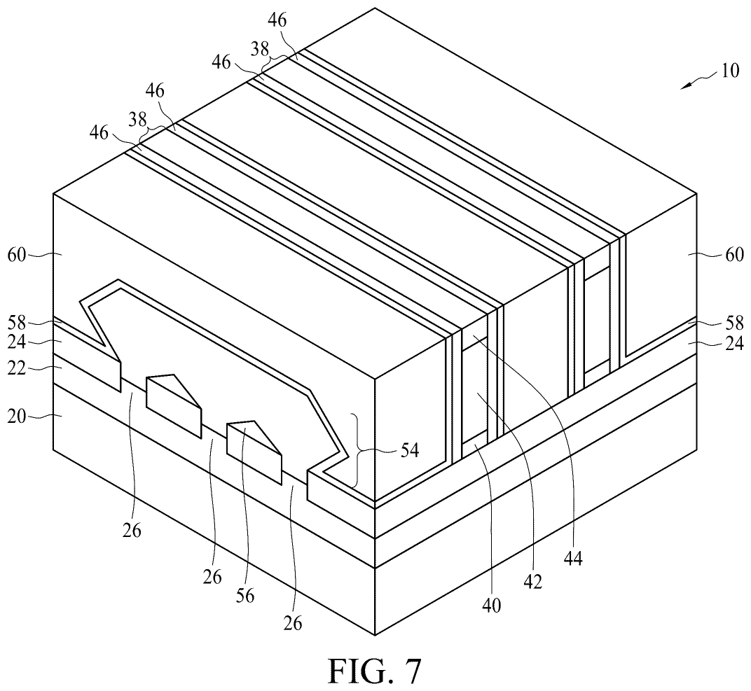

FIG. 7 illustrates a perspective view of the structure after the formation of Contact Etch Stop Layer (CESL) 58 and Inter-Layer Dielectric (ILD) 60. The respective process is illustrated as process 214 in the process flow 200 as shown in FIG. 28. CESL 58 may be formed of silicon oxide, silicon nitride, silicon carbo-nitride, or the like, and may be formed using CVD, ALD, or the like. ILD 60 may include a dielectric material formed using, for example, FCVD, spin-on coating, CVD, or another deposition method. ILD 60 may be formed of a dielectric material, which may include silicon oxide, Phospho-Silicate Glass (PSG), Boro-Silicate Glass (BSG), Boron-Doped Phospho-Silicate Glass (BPSG), or the like. A planarization process such as a CMP process or a mechanical grinding process may be performed to level the top surfaces of ILD 60, dummy gate stacks 38, and gate spacers 46 with each other.

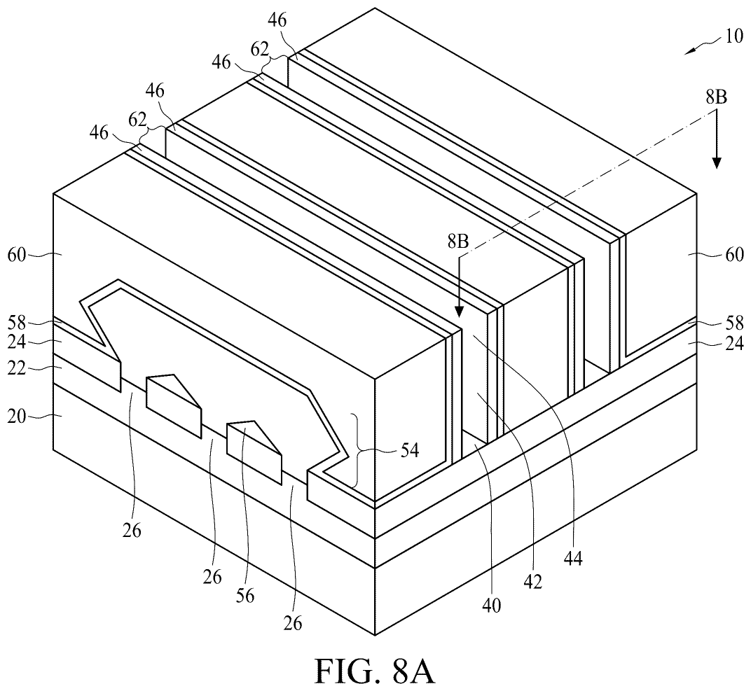

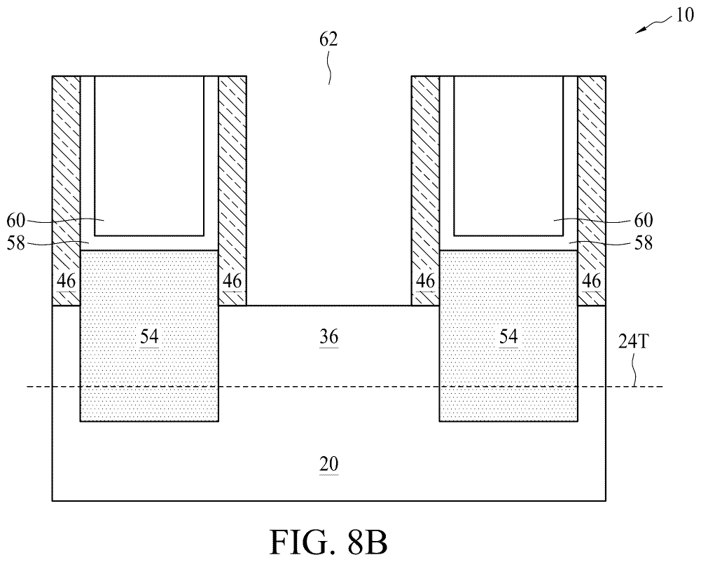

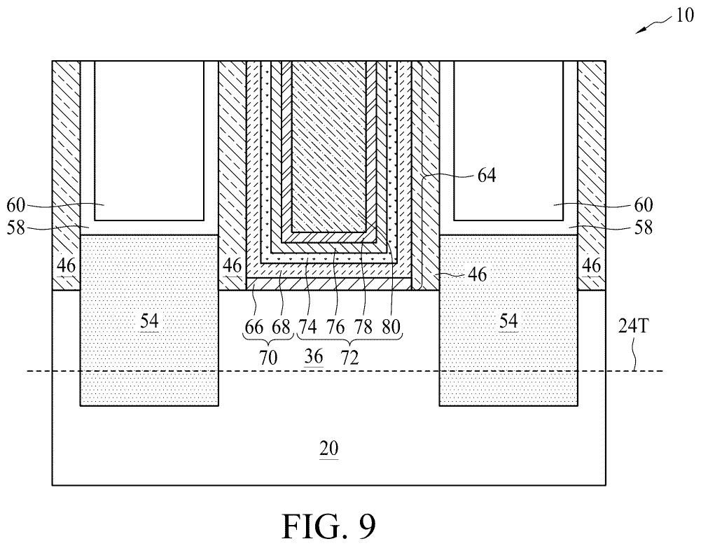

After the structure shown in FIG. 7 is formed, the dummy gate stacks 38 are replaced with replacement gates stacks, as shown in the processes in FIGS. 8A, 8B, and 9. In FIG. 8B, the top surface 24T of STI regions 24 are illustrated, and semiconductor fin 36 protrudes higher than top surface 24T.

To form the replacement gates, hard mask layers 44, dummy gate electrodes 42, and dummy gate dielectrics 40 as shown in FIG. 7 are removed, forming openings 62 as shown in FIG. 8A. The respective process is illustrated as process 216 in the process flow 200 as shown in FIG. 28. The top surfaces and the sidewalls of protruding 36 are exposed to openings 62, respectively.

FIG. 8B illustrates the vertical cross-section 8B-8B as shown in FIG. 8A. Next, as shown in FIG. 9, replacement gate stack 64 is formed. The respective process is illustrated as process 218 in the process flow 200 as shown in FIG. 28. Gate stack 64 includes gate dielectric 70 and gate electrode 72. Gate dielectric 70 may include Interfacial Layer (IL) 66 and high-k dielectric layer 68. IL 66 is formed on the exposed surfaces of protruding fins 36, and may include an oxide layer such as a silicon oxide layer, which is formed through the thermal oxidation of protruding fins 36, a chemical oxidation process, or a deposition process. High-k dielectric layer 68 includes a high-k dielectric material such as hafnium oxide, lanthanum oxide, aluminum oxide, zirconium oxide, or the like. The dielectric constant (k-value) of the high-k dielectric material is higher than 3.9, and may be higher than about 7.0. In accordance with some embodiments, high-k dielectric layer 68 is formed using ALD or CVD.

Referring further to FIG. 9, gate electrode 72 is formed on gate dielectric 70. Gate electrode 72 may include a diffusion barrier layer (a capping layer) 74 and one or more work function layer 76 over the diffusion barrier layer 74. Diffusion barrier layer 74 may be formed of titanium nitride, which may (or may not) be doped with silicon. Titanium nitride, when doped with silicon, is also sometimes referred to as titanium silicon nitride (Ti—Si—N, or TSN). Work function layer 76 determines the work function of the gate electrode, and includes at least one layer, or a plurality of layers formed of different materials. The specific material of the work function layer may be selected according to whether the respective FinFET is an n-type FinFET or a p-type FinFET. For example, when the FinFET is an n-type FinFET, work function layer 76 may include a TaN layer and a titanium aluminum (TiAl) layer over the TaN layer. When the FinFET is a p-type FinFET, work function layer 76 may include a TaN layer, a TiN layer over the TaN layer, and a TiAl layer over the TiN layer. After the deposition of the capping layer 74 and the work function layer 76, blocking layer 78, which may be another TiN layer, is formed. Blocking layer 78 may be formed using CVD.

Next, metal-filling region 80 is deposited, which has a bottom surface in physical contact with the top surface of blocking layer. The formation of metal-filling region 80 may be achieved through CVD, ALD, Physical Vapor Deposition (PVD), or the like, and metal-filling region 80 may be formed of or comprise cobalt, tungsten, alloys thereof, or other metal or metal alloys.

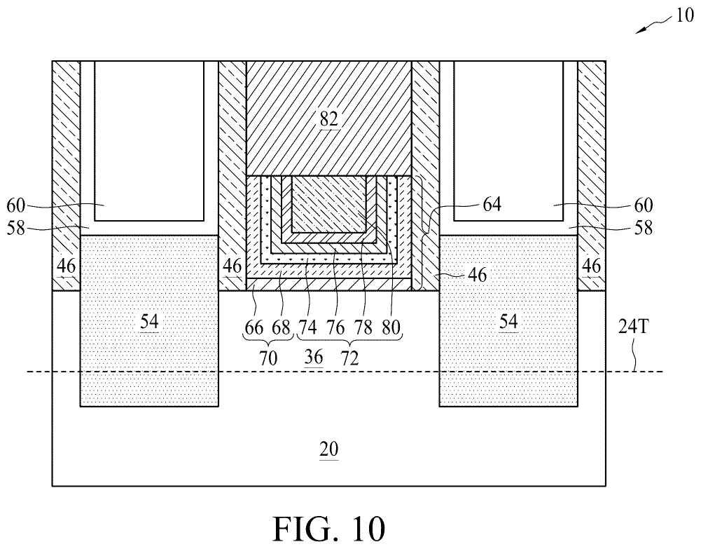

A planarization such as a Chemical Mechanical Polish (CMP) process or a mechanical grinding process is then performed, so that the top surface of gate stack 64 is coplanar with the top surface of ILD 60. In a subsequent process, gate stack 64 is etched back, resulting in a recess formed between opposite gate spacers 46. Next, as shown in FIG. 10, hard mask 82 is formed over replacement gate stack 64, as shown in FIG. 10. In accordance with some embodiments, the formation of hard mask 82 includes a deposition process to deposit a dielectric to fill the recess, followed by a planarization process to remove the excess dielectric material over gate spacers 46 and ILD 60. Hard mask 82 may be formed of silicon nitride, for example, or other like dielectric materials.

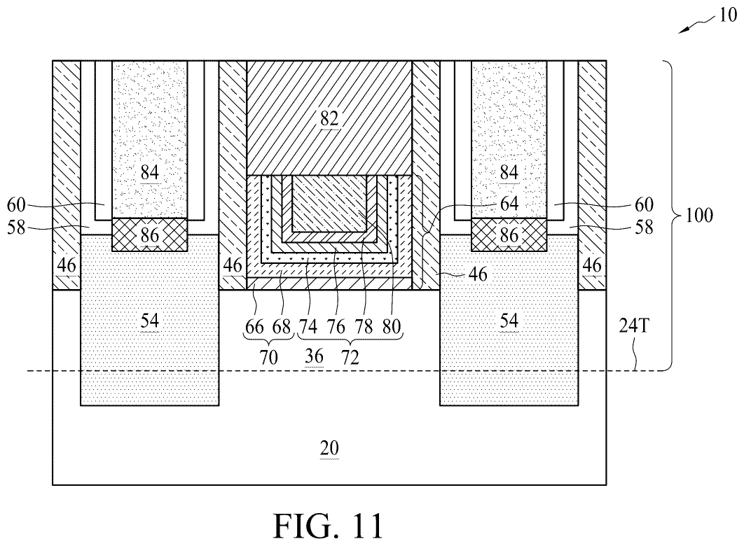

FIG. 11 illustrates the formation of lower source/drain contact plugs 84 and silicide regions 86. The respective process is illustrated as process 220 in the process flow 200 as shown in FIG. 28. In accordance with some embodiments, the formation process includes etching ILD 60 and CESL 58 to form contact openings, depositing a metal layer (such as a titanium layer or a cobalt layer) extending into the contact openings, and performing an anneal process, so that the bottom portion of the metal layer reacts with source/drain region 54 to form silicide regions 86. The remaining sidewall portions of the metal layer may be removed or left un-removed.

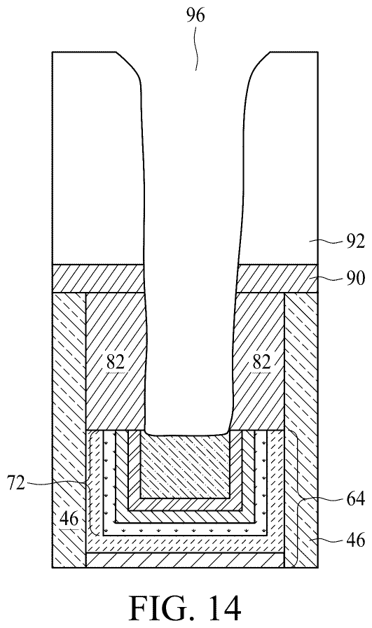

Source/drain contact plugs 84 are then formed to contact source/drain silicide regions 86. FinFET 100 is thus formed. In accordance with some embodiments, source/drain contact plugs 84 may be formed of tungsten. The formation process may include depositing a tungsten liner, and depositing additional tungsten layers over the tungsten liner. The Formation process may be the same as the formation of contact plugs 98, and the structures, materials, and the formation processes are the same as described referring to FIGS. 14-22. In accordance with alternative embodiments, source/drain contact plugs 84 may comprise cobalt, tungsten, other applicable metals, or the alloys thereof. A planarization such as a CMP process or a mechanical grinding process is performed to level the top surface of contact plugs 84 with the top surface of ILD 60.

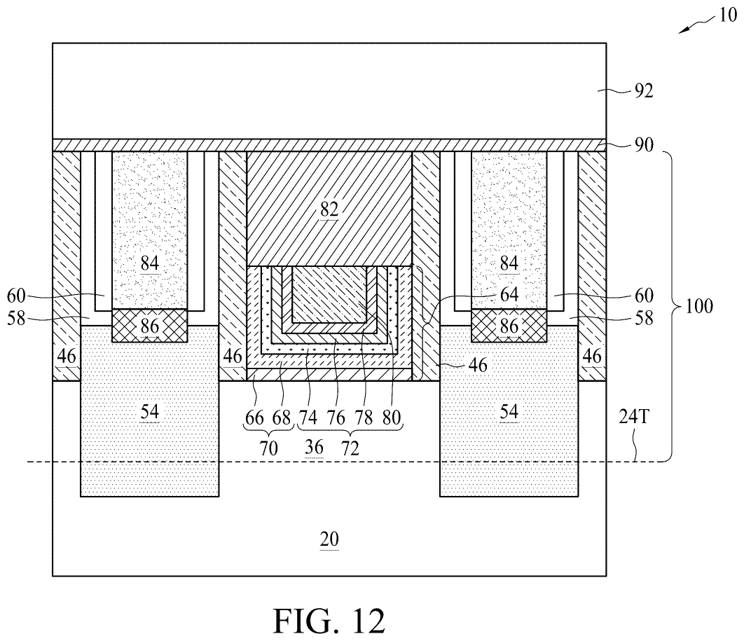

FIG. 12 illustrates the formation of Etch Stop Layer (ESL) 90 and dielectric layer 92 (which may also be an ILD) over ESL 90. The respective process is illustrated as process 222 in the process flow 200 as shown in FIG. 28. ESL 90 may be formed of or comprise aluminum oxide, aluminum nitride, silicon oxynitride, silicon carbon nitride, silicon carbon oxide, the like, or a combination thereof. Dielectric layer 92 may comprise or be silicon dioxide, a low-k dielectric material, silicon oxynitride, PSG, BSG, BPSG, USG, FSG, SiOC, ESL 90 and dielectric layer 92 may be deposited by using spin-on coating, CVD, ALD, LPCVD, PECVD or the like.

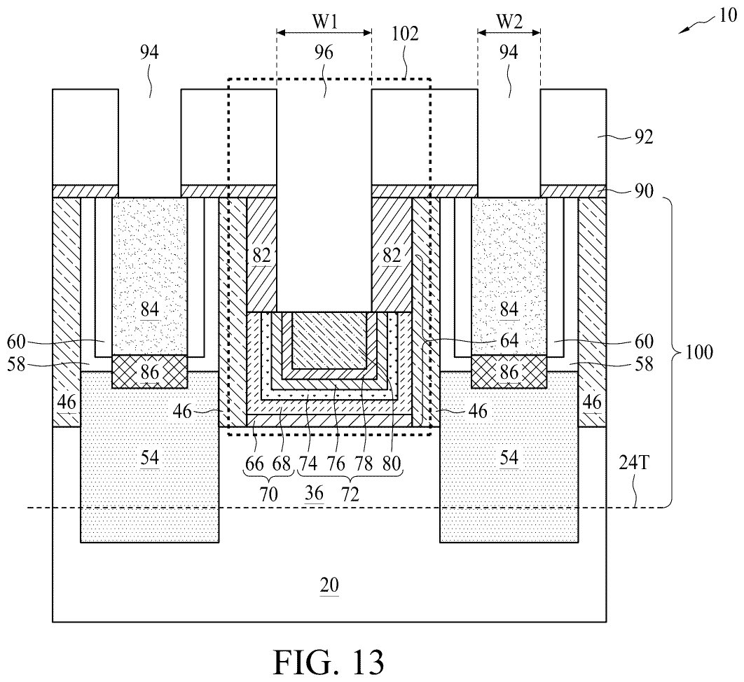

FIG. 13 illustrates the formation of source/drain contact openings 94 and gate contact openings 96 through etching to reveal contact plugs 84 and gate electrode 72, respectively. The respective process is illustrated as process 224 in the process flow 200 as shown in FIG. 28. Dielectric layer 92 and ESL 90 may be etched, for example, using photolithography and one or more etch processes. The etch process may include a dry etch process using Reactive Ion Etch (RIE), Neutral Beam Etch (NBE), Inductively Coupled Plasma (ICP) etch, Capacitively Coupled Plasma (ICP) etch, Ion Beam Etch (IBE), the like, or a combination thereof. The etch process may be anisotropic. The widths W1 of gate contact opening 96 and W2 of source/drain contact opening 94 may be in the range between about 50 Å and about 1,000 Å.

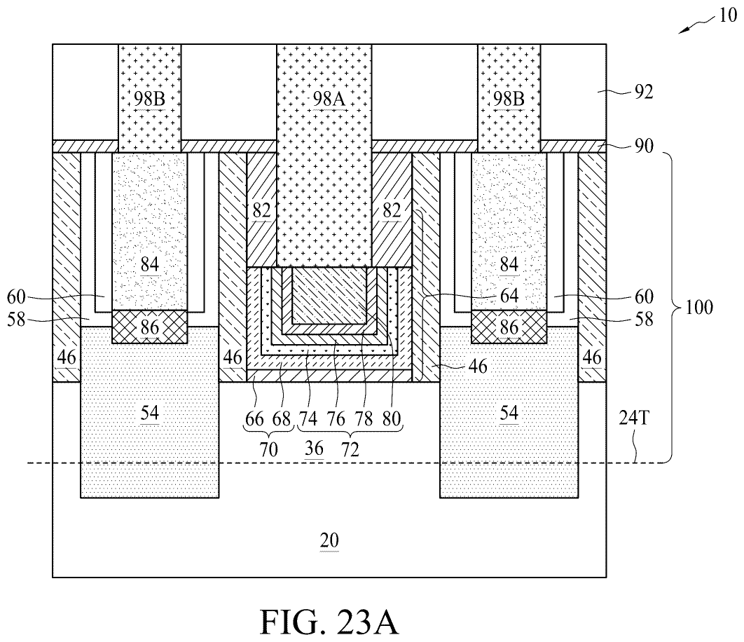

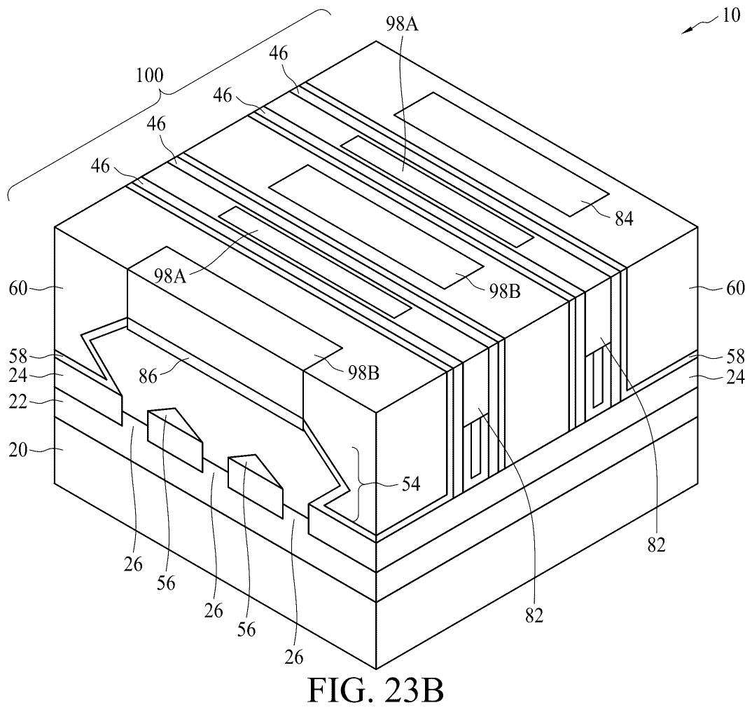

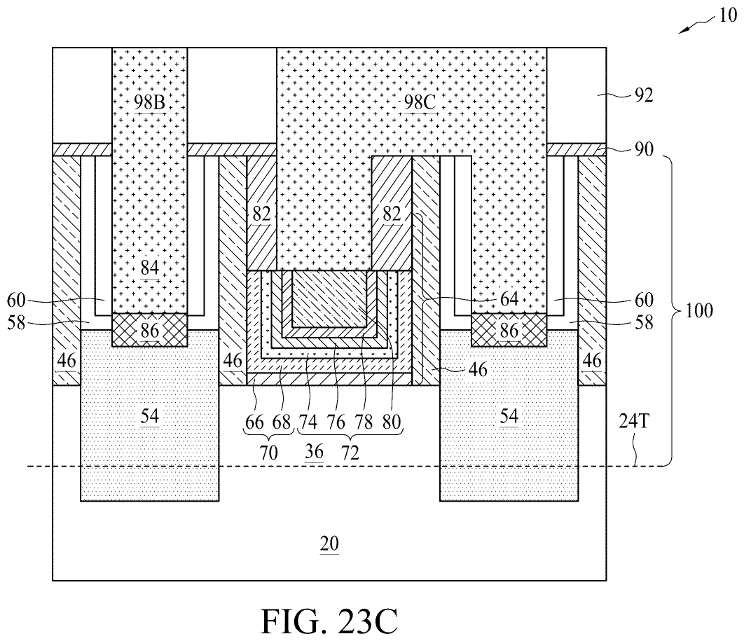

FIGS. 14 through 18 illustrate the cross-sectional views of intermediate stages in the formation of gate contact plugs 98A in accordance with some embodiments. In the illustrated cross-sectional views, the formation of the gate contact plugs 98A (Also refer to FIGS. 23A and 23B) is illustrated as an example. The formation process may also be used for forming other contact plugs including and not limited to source/drain contact plugs, the contact plugs over the gate contact plugs and source/drain contact plugs, butted contact plugs, and the like. For example, when the gate contact opening 96 is filled to form gate contact plugs 98A, the sourced/drain contact openings 94 may be simultaneously filled in same processes and using same materials to form source/drain contact plugs 98B (FIG. 23A).

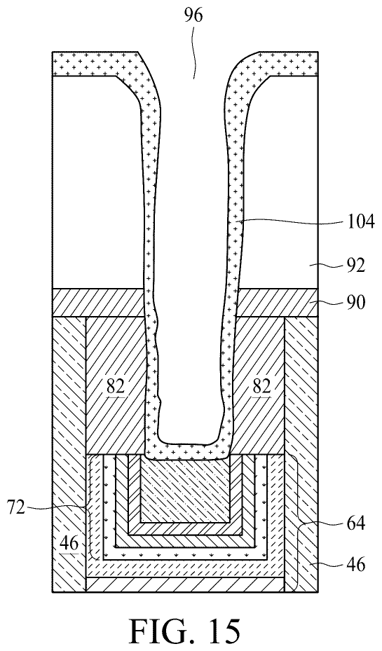

FIG. 14 illustrates a cross-sectional view, wherein the region 102 in FIG. 13 is shown in the cross-sectional view. Gate electrode 72 is exposed to gate contact opening 96. Next, referring to FIG. 15, tungsten liner 104 is deposited. The respective process is illustrated as process 226 in the process flow 200 as shown in FIG. 28. There may not be metal cap such as titanium cap formed on gate electrode 72. Tungsten liner 104 is thus in physical contact with the top surface of gate electrode 72, and in contact with dielectric materials such as hard mask 82, ESL 90, and ILD 92. In accordance with some embodiments in which gate spacers 46 are exposed to gate contact opening 96, tungsten liner 104 is also in physical contact with gate spacers 46.

The deposition of tungsten liner 104 may be performed using PVD in a PVD chamber. In accordance with some embodiments, in the PVD chamber, a tungsten target is placed over wafer 10, and the spacing between the tungsten target and wafer 10 may be in the range between about 10 mm and about 1,000 mm. The tungsten target may use substantially pure tungsten, with the tungsten purity being 5N5 (higher than about 99.9995%), for example.

During the PVD process for depositing tungsten liner 104, the wafer temperature of wafer 10 may be in the range between room temperature (such as around 21° C.) and about 500° C. The source power may be a DC power or an RF power, which may be in the range between about 100 watts and about 50,000 watts. When the RF power is used, the frequency of the RF power may be in the range between about 2 MHz and about 60 MHz. The bias power (plasma power) may be in the range between about 0 watts and about 2,000 watts. In accordance with some embodiments, the sputtering may be performed using a gas such as Ar, Kr, or combinations thereof. The gas flow may be in the range between about 1 sccm and about 5,000 sccm. The PVD chamber pressure may be in the range about 0.1 mTorr and about 500 mTorr. Pull-in or pull-out ion directional control may be adopted.

In accordance with some embodiments, since the tungsten liner 104 is deposited using a tungsten target through PVD, and no elements such as boron, chlorine, fluorine, and the like are in the tungsten target and the PVD chamber, the resulting tungsten liner 104, as deposited, may be free from the elements such as boron, chlorine, and fluorine.

The tungsten liner 104 is more advantageous than other types of liners such as Ti/TiN (including a Ti layer and a TiN layer over the Ti layer) liners. For example, the tungsten liner 104 is smoother with smaller surface roughness than the Ti/TiN liners. The roughness of the liners may be transferred to the subsequently deposited tungsten layers, and may cause seams (voids). With the tungsten liner 104 having smaller roughness, the subsequently deposited tungsten layers also have smooth surfaces, and are less likely to have seams. By adopting a tungsten liner, if seams are ever generated, the seams will be narrower.

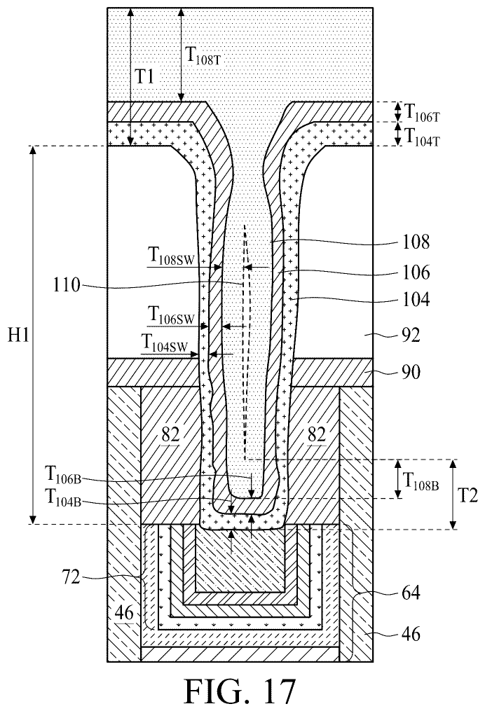

Using PVD to form tungsten liner 104 may suffer from low coverage problem. FIG. 17 illustrates some example thicknesses of tungsten liner 104. The thickness values indicate that the sidewall portions of tungsten liner 104 are thinner than top and bottom portions. The sidewalls of the dielectric materials facing gate contact opening 96 may not be fully covered by tungsten liner 104.

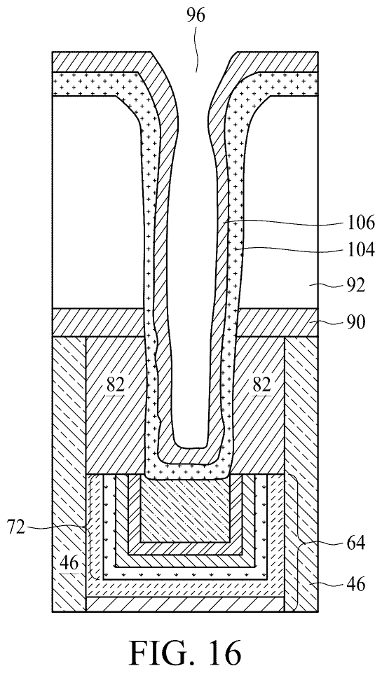

Referring to FIG. 16, nucleation layer 106 is deposited to fully cover the sidewalls of the dielectric materials. The respective process is illustrated as process 228 in the process flow 200 as shown in FIG. 28. Nucleation layer 106 is also a tungsten layer, and may be deposited using ALD, CVD, or the like. Also, in order to form nucleation layer 106 with better coverage, the temperature for depositing nucleation layer 106 may be lower than the deposition temperature of bulk tungsten layer 108 to reduce the deposition rate.

In accordance with some embodiments, nucleation layer 106 is a fluorine-containing tungsten layer, which is formed using a fluorine-containing tungsten precursor. In accordance with some embodiments, the fluorine-containing tungsten precursor includes tungsten hexafluoride (WF₆) or other applicable precursors. The precursor further includes a reducing agent such as diborane (B₂H₆), hydrogen (H₂), a silicon-containing precursor such as silane, or combinations thereof. The formation may be performed through (thermal) ALD. The ALD process may include a plurality of cycles, each comprising pulsing the fluorine-containing tungsten precursor, turning off the conduction of the fluorine-containing tungsten precursor, pulsing the reducing agent, and turning off the conduction of the reducing agent.

In accordance with some embodiments, since the tungsten precursor includes fluorine, the resulting nucleation layer 106 (as deposited) may include fluorine. When the reducing agent comprises boron, the resulting nucleation layer 106 may also include boron as deposited. When the reducing agent comprises a silicon-containing precursor such as silane, the resulting tungsten liner 104 may also include silicon as deposited.

In accordance with some embodiments, nucleation layer 106 is a fluorine-free tungsten layer, which is formed using a fluorine-free tungsten precursor. In accordance with some embodiments, the fluorine-free tungsten precursor includes tungsten hexafluoride (WCl₅), tungsten pentachloride (W₂Cl₁₀) or the like. The tungsten pentachloride is a solid at room temperature, which is turned into gaseous phase when used. The precursor further includes a reducing agent such as hydrogen (H₂), a silicon-containing precursor such as silane, or the like.

The formation of the fluorine-free nucleation layer 106 may be performed through (thermal) ALD, while other processes such as CVD may be used. When an ALD process is adopted, the ALD process may include a plurality of cycles, each comprising pulsing the fluorine-free tungsten precursor, turning off the conduction of the fluorine-free tungsten precursor, pulsing the reducing agent, and turning off the conduction of the reducing agent. When a CVD process is adopted, the fluorine-free tungsten precursor and the reducing agent are both conducted into the respective CVD chamber at the same time to deposit nucleation layer 106. The CVD process may also be a thermal process without plasma.

In the formation of nucleation layer 106, to ensure the formation of the nucleation layer to have full coverage on the sidewalls of the dielectric materials, the temperature of the respective wafer is low, for example, lower than the temperatures for forming the subsequently formed bulk tungsten layer 10. The temperature may also be higher than, equal to, or lower than the wafer temperature during PVD process for forming tungsten liner 104.

During the ALD process for depositing the nucleation layer 106 that is fluorine-free, the wafer temperature of wafer 10 may be in the range between about 300° C. and about 500° C. The source power may be in the range between about 0 watts (if the ALD or CVD process is a thermal process) and about 5,000 watts. The plasma may be generated through ICP, CCP, microwave, or the like. The plasma (if used) may be remote plasma or direct plasma. Furthermore, the plasma may be, or may not be, filtered to remove ions, and leaving radicals of the process gas.

In accordance with yet alternative embodiments, during the deposition of fluorine-free nucleation layer 106, the chamber pressure may be in the range between about 1 Torr and about 100 Torr. The gas flow rate may be in the range between about 1 sccm and about 10,000 sccm. The tungsten-containing gas may have a flow rate percentage (in the process gas) in the range between about 0.01% and about 100%.

In accordance with some embodiments, since the nucleation layer 106 may include fluorine, the resulting tungsten liner 104 (as deposited) may include fluorine. The fluorine atomic percentage, however, may be low. When the reducing agent comprises a silicon-containing precursor such as silane, the resulting tungsten liner 104 may also include silicon as deposited.

In accordance with some embodiments, between the deposition of the tungsten liner 104 and nucleation layer 106 (regardless of the process gases for forming nucleation layer 106), there may be, or may not be, vacuum break. The formation of nucleation layer 106 and the subsequent deposition of bulk tungsten layer 108 (FIG. 17) may be performed in a same vacuum platform in different vacuum chamber, and there is no vacuum break in between.

FIG. 17 illustrates the deposition of bulk tungsten layer 108 in accordance with some embodiments. The respective process is illustrated as process 230 in the process flow 200 as shown in FIG. 28. In accordance with some embodiments, the deposition of bulk tungsten layer 108 is performed using a thermal CVD process (which may not have plasma generated). The deposition of bulk tungsten layer 108 may be performed using WF₆ and H₂ as process gases. In accordance with some embodiments, in the formation of nucleation layer 106, precursor flow is adequately provided to ensure full coverage. Accordingly, the transition from the formation of nucleation layer 106 to the formation of bulk tungsten layer 108 may by achieved by increase the temperature of the wafer, while other process conditions such as precursor flow rate, chamber pressure, and the like, may remain unchanged.

In accordance with some embodiments, the deposition of bulk tungsten layer 108 is performed with the hydrogen flow rate being in the range between about 1,000 sccm and about 7,000 sccm, and the WF₆ flow rate being in the range between about 50 sccm and about 450 sccm. The pressure in the respective chamber may be in the range between about 10 Torr and about 300 Torr.

In accordance with some embodiments, bulk tungsten layer 108 and tungsten liner 104 may be distinguishable from each other. For example, when Transmission Electron Microscopy (TEM) is used, the images of the bulk tungsten layer 108 and tungsten liner 104 may be distinguished from each other from their different patterns such as different grey levels and dark/light patterns. Furthermore, nucleation layer 106, due to its lower deposition, may be more amorphous than bulk tungsten layer 108 and tungsten liner 104, and hence may also be distinguished from bulk tungsten layer 108 and tungsten liner 104.

As aforementioned, as a result of forming tungsten liner 104, the tungsten liner 104 has smooth top surface (FIG. 15) with smaller roughness, for example, than the Ti/TiN liner if it is used. Accordingly, the nucleation layer 106 and bulk tungsten layer 108 are also smoother with smaller roughness. As a result, air gap 110, if formed, will be narrower than the air gap generated when a Ti/TiN liner is used. The air gap 110 may also be eliminated due to the using of the tungsten liner. The reduction in the air gap results in the increase in the volume of tungsten. Accordingly, replacing the Ti/TiN liner with tungsten liner also reduces the contact resistance of the resulting contact plugs.

Some of the example dimensions are marked in FIG. 17. The top portion of the tungsten layers 104/106/108 may have a total top thickness Ti in the range between about 30 Å and about 2,000 Å, and the bottom portion of the tungsten layers 104/106/108 may have a total bottom thickness T2 in the range between about 10 Å and about 1,000 Å. The grain size of the top portion of the tungsten layers may be in the range between about 30 Å and about 2,000 Å. The grain size of the bottom portion of the tungsten layers may be smaller than the grain size of the top portion of the tungsten layers, and may be in the range between about 30 Å and about 1,000 Å.

Tungsten liner 104 may have top thickness T_{104T} in the range between about 30 Å and about 100 Å. The sidewall thickness T_{104SW} of tungsten liner 104 is smaller than top thickness T_{104T} (hence may suffer from coverage problem), and may be in the range between about 5 Å and about 30 Å. The bottom thickness T_{104B} may be in the range between about 10 Å and about 100 Å. Tungsten nucleation layer 106, which may be conformal, may have top thickness T_{106T}, sidewall thickness T_{106SW}, and bottom thickness T_{106B} in the range between about 0 Å (when not formed) and about 30 Å. Bulk tungsten layer 108 may have top thickness T_{108T}, sidewall thickness T_{108SW}, and bottom thickness T_{108B} in the range between about 30 Å and about 2,000 Å.

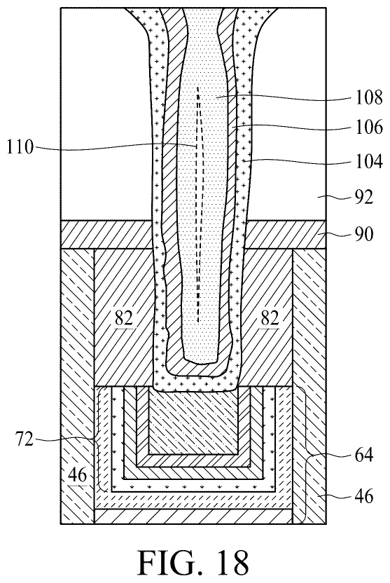

FIG. 18 illustrates a planarization process, so that the excess portions of tungsten liner 104, nucleation layer 106, and bulk tungsten layer 108 higher than ILD 92 are removed. The respective process is illustrated as process 232 in the process flow 200 as shown in FIG. 28. Gate contact plug 98A is thus formed. In the same processes for forming gate contact plug 98A, source/drain contact plugs 98B (FIG. 23A) may also be formed.

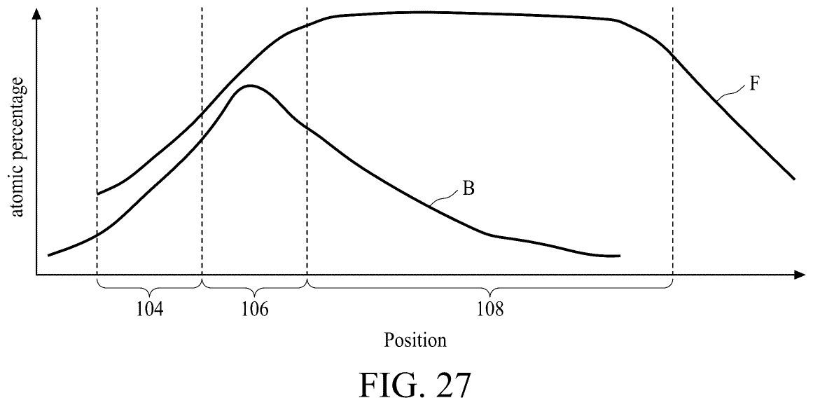

FIG. 27 illustrates an example distribution profile of fluorine and boron when B₂H₆ is used for forming nucleation layer 106, and WF₆ is used for forming bulk tungsten layer 108 in accordance with some embodiments. Boron has a peak atomic percentage (and concentration) in nucleation layer 106, and the atomic percentage (and concentration) of boron gradually reduce in the directions going into tungsten liner 104 and bulk tungsten layer 108. Also, fluorine may have a peak atomic percentage (and concentration) in bulk tungsten layer 108, and the atomic percentage (and concentration) of fluorine gradually reduces in the directions going into nucleation layer 106 and tungsten liner 104. If silane is used for forming nucleation layer 106, the silane may also have similar profile as that of boron, and has peak concentration in nucleation layer 106.

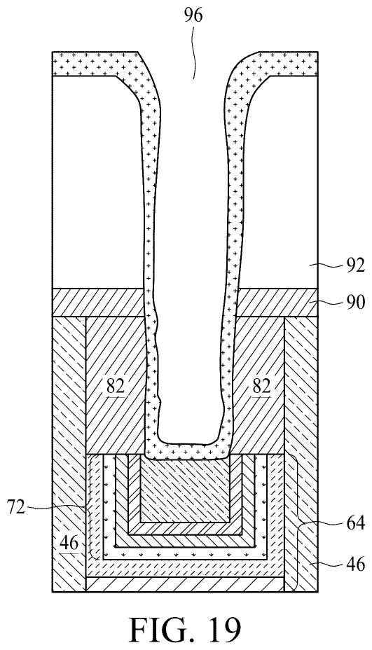

FIGS. 19 through 22 illustrates the formation of contact plugs using tungsten liners in accordance with alternative embodiments. Unless specified otherwise, the materials, the structures, and the formation processes of the components in these embodiments are essentially the same as the like components denoted by like reference numerals in the preceding embodiments in FIGS. 14 through 18. The details regarding the materials, the structures, and the formation processes of the components shown in FIGS. 19 through 22 may thus be found in the discussion of the preceding embodiments.

The initial processes of these embodiments are essentially the same as shown in FIG. 1 through FIG. 13. Next, as shown in FIG. 19, tungsten liner 104 is deposited. The deposition process is essentially the same as discussed referring to FIG. 15, and hence are not repeated herein.

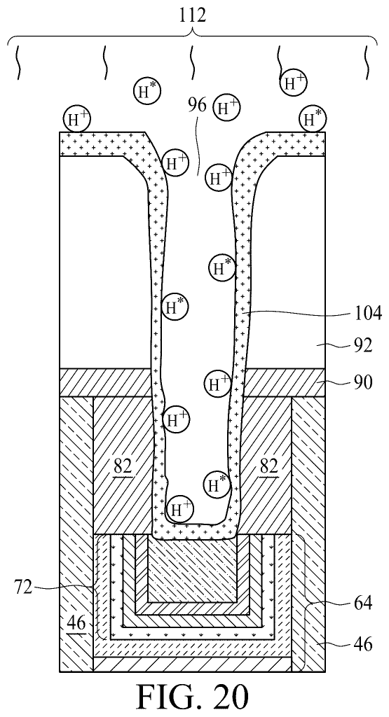

Referring to FIG. 20, without depositing nucleation layer 106, a hydrogen treatment process 112 is performed to treat tungsten liner 104. The respective process is illustrated as process 229 in the process flow 200 as shown in FIG. 28. Since the tungsten liner 104 is not conformal enough, and it is possible that some surfaces of the dielectric materials such as and mask 72, ESL 90, and ILD 92 are not covered by tungsten liner 104. The hydrogen treatment process 112 may generate dangling bonds for the exposed dielectric material, and improve the nucleation of tungsten for the subsequent formation of bulk tungsten layer 108.

The hydrogen treatment may be performed using process gases comprising hydrogen (H₂), while inert gases such as Ar may be added into H₂. The chamber pressure may be in the range between about 1 mTorr and about 50,000 mTorr. The gas flow rate may be in the range between about 1 sccm and about 10,000 sccm. The hydrogen flow rate percentage in the process gas may be in the range between about 0.1% and about 100%.

The treatment may include a thermal process (with plasma being off) and/or a plasma treatment process, in which the wafer 10 may be heated, and/or plasma may be turned on. The wafer temperature may be in the range between room temperature (for example, about 21° C.) and about 500° C. when plasma treatment is adopted. When the thermal treatment is adopted, the wafer temperature may be in the range between about 150° C. and about 500° C. The plasma power (if plasma is adopted) may be lower than about 5,000 watts, and may be in the range between about 50 watts and about 5,000 watts. The plasma may be generated through ICP, CCP, microwave, or the like. The plasma may be remote plasma or direct plasma. Furthermore, the plasma may be, or may not be, filtered to remove ions, and leaving radicals (including hydrogen radicals) for the treatment.

The hydrogen treatment process 112 is performed before the deposition of bulk tungsten layer 108. There may be, or may not be, vacuum break between the formation of tungsten liner 104 and the subsequent deposition of bulk tungsten layer 108 (FIG. 17). In accordance with some embodiments, the hydrogen treatment process 112 may be performed in the same chamber (and in the same vacuum environment (without vacuum break)) for depositing bulk tungsten layer 108 (FIG. 17), so that the dangling bonds generated by the hydrogen treatment will not be recombined due to the exposure of air until the deposition of the bulk tungsten layer 108. In accordance with alternative embodiments, the hydrogen treatment process 112 may be performed in the PVD chamber (and in the same vacuum environment (without vacuum break)) for depositing tungsten liner 104. In accordance with yet alternative embodiments, two hydrogen treatment processes 112 are performed, with one being performed in the PVD chamber, and the other one being performed in the same chamber (and in the same vacuum environment (without vacuum break)) for depositing bulk tungsten layer 108 (FIG. 17).

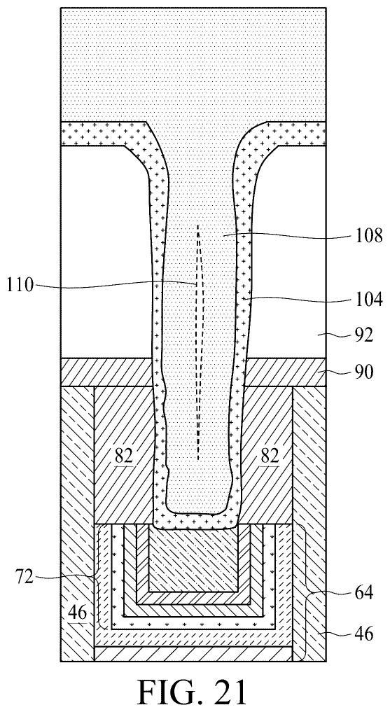

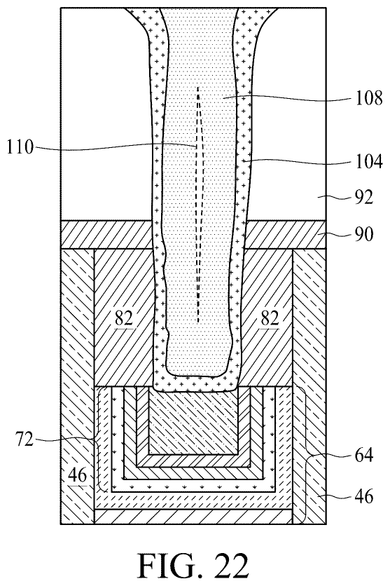

FIG. 21 illustrates the deposition of bulk tungsten layer 108. The deposition process is essentially the same as discussed referring to FIG. 17, and hence are not repeated herein. FIG. 22 illustrates the planarization process, so that gate contact plug 98A is formed. In the same processes for forming gate contact plug 98A, source/drain contact plugs 98B are also formed, as shown in FIG. 23A.

FIG. 23B illustrates a perspective view of the structure shown in FIG. 23A, in which gate contact plug 98A and source/drain contact plugs 98B are illustrated. FIG. 23C illustrates an alternative embodiment in which butted contact plug 98C is formed. The processes for forming butted contact plug 98C is essentially the same as shown in FIGS. 14 through 22, and includes the formation of tungsten liners. The details are not repeated herein. The tungsten liner 104 and nucleation layer 106 will have contours following the sidewalls and the bottoms of butted contact plug 98C.

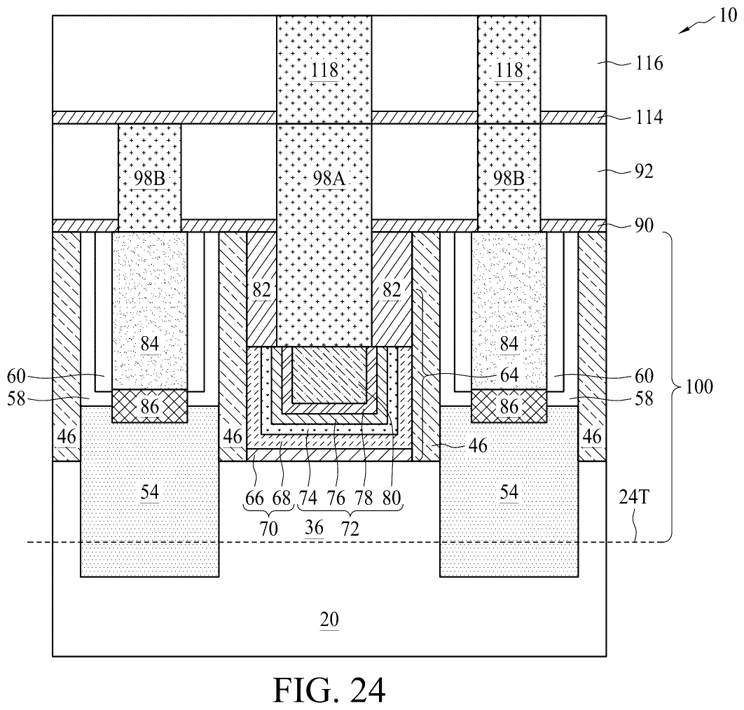

FIG. 24 illustrates the formation of upper structures, which include ESL 114, ILD 116, and contact plugs 118. The materials, structures, and formation processes may be essentially the same as that of ESL 90, ILD 92, and contact plugs 98, respectively, and are not repeated herein.

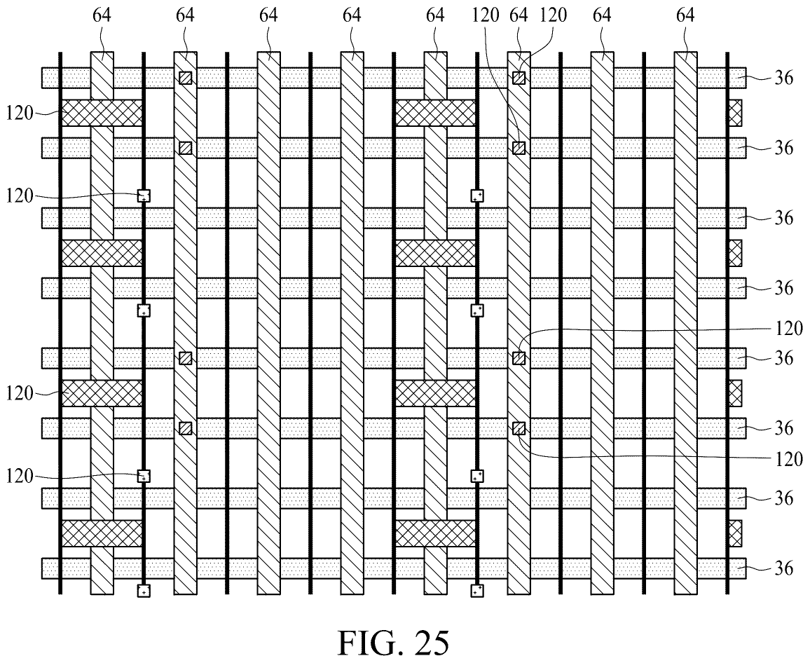

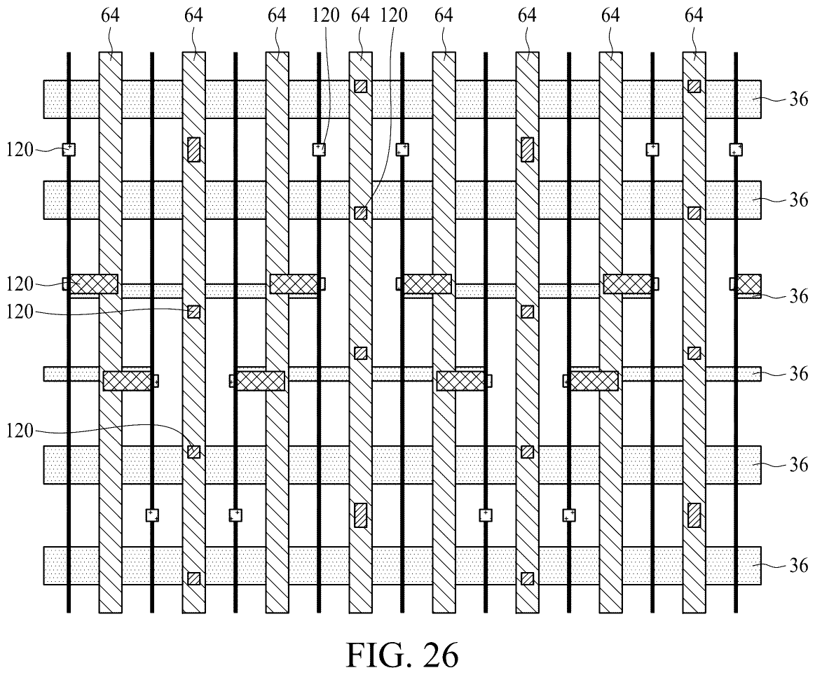

The contact plugs adopting the tungsten liners may be applied to all contact plugs in integrated circuits, which include, and are not limited to, source/drain contact plugs, gate contact plugs, the upper contact plugs over the source/drain contact plugs and the gate contact plugs, butted contact plugs, and the like. FIG. 25 illustrates a schematic top view of a logic circuit. The active regions (which may be semiconductor regions for semiconductor fins, semiconductor nanostructure, or the like) 36 and gate stacks 64 are illustrated. A plurality of contact plugs 120, which may represent the contact plugs 98 and 118 as aforementioned, and higher-level contact plugs, are illustrated. FIG. 26 illustrates a schematic top view of a Static Random-Access Memory (SRAM) circuit. The contact plugs, vias, etc. in the illustrated top views may all be formed using the embodiments of the present disclosure, and are represented as 120.

Tungsten contact plugs may have two phases, alpha phase and beta phase. The corresponding tungsten is referred to as α-phase tungsten (α-W) and β-phase tungsten (β-W), respectively. The resistivity of β-W is much higher (sometimes six times higher) than the resistivity of α-W. Experiment results have revealed that by adopting the embodiments of the present disclosure, the possibility of forming α-phase tungsten is increased. For example, when Ti/TiN is used to form the liners of contact plugs, the tungsten in 20 percent of the contact plugs are α-phase tungsten. As a comparison, when tungsten is used to form the liners of contact plugs, the tungsten in 100 percent of the contact plugs are α-phase tungsten.

The embodiments of the present disclosure have some advantageous features. The contact plugs formed in accordance with the embodiments of the present are barrier free. By adopting tungsten liners, the seams in contact plugs are reduced or eliminated. This results in the volume of the tungsten to be increased. Furthermore, more contact plugs with α-phase tungsten may be formed, further resulting in the reduction of contact plugs.

In accordance with some embodiments, a method comprises forming a dielectric layer over a conductive feature; etching the dielectric layer to form an opening, wherein the conductive feature is exposed through the opening; forming a tungsten liner in the opening, wherein the tungsten liner contacts sidewalls of the dielectric layer; depositing a tungsten layer to fill the opening; and planarizing the tungsten layer, wherein portions of the tungsten layer and the tungsten liner in the opening form a contact plug. In an embodiment, the depositing the tungsten layer comprises depositing a tungsten nucleation layer on the tungsten liner; and depositing a bulk tungsten layer on the tungsten nucleation layer. In an embodiment, the depositing the tungsten nucleation layer is performed using a precursor comprising tungsten chloride. In an embodiment, the depositing the tungsten nucleation layer is performed using a precursor comprising tungsten fluoride.

In an embodiment, the depositing the bulk tungsten layer is performed using a precursor comprising tungsten fluoride. In an embodiment, the depositing the tungsten layer comprises performing a hydrogen treatment process on the tungsten liner using hydrogen (H₂) as a process gas; and depositing a bulk tungsten layer on the tungsten liner. In an embodiment, the hydrogen treatment process comprises a thermal treatment process. In an embodiment, the hydrogen treatment process comprises a plasma treatment process. In an embodiment, the tungsten liner and the tungsten layer are free from titanium therein. In an embodiment, the contact plug comprises a source/drain contact plug. In an embodiment, the contact plug comprises a gate contact plug. In an embodiment, the tungsten liner comprises substantially pure tungsten.

In accordance with some embodiments, a method comprises forming a gate stack on a semiconductor region; forming a source/drain region on a side of the gate stack; depositing a contact etch stop layer over the source/drain region; depositing an inter-layer dielectric over the contact etch stop layer; etching the inter-layer dielectric and the contact etch stop layer to form a source/drain contact opening; forming a dielectric hard mask over the gate stack; etching the dielectric hard mask to form a gate contact opening; and forming a contact plug in one of the source/drain contact opening and the gate contact opening, wherein the forming the contact plug comprises depositing a tungsten liner through physical vapor deposition; and depositing a bulk tungsten layer over the tungsten liner through chemical vapor deposition.

In an embodiment, the tungsten liner is deposited as a substantially pure tungsten layer. In an embodiment, the method further comprises, between the depositing the tungsten liner and the depositing the bulk tungsten layer performing a hydrogen treatment process on the tungsten liner. In an embodiment, the method further comprises depositing a nucleation layer over the tungsten liner using a fluorine-containing process gas, wherein the bulk tungsten layer is deposited on the nucleation layer. In an embodiment, the method further comprises depositing a nucleation layer over the tungsten liner using a chlorine-containing process gas, wherein the bulk tungsten layer is deposited on the nucleation layer.

In accordance with some embodiments, a method comprises forming a transistor comprising forming a gate stack on a semiconductor region; and forming a source/drain region adjacent to the gate region; and forming a contact plug in a dielectric layer, wherein the contact plug is over and electrically coupled to one of the gate stack and the source/drain region, wherein an entirety of the contact plug is formed of tungsten, and wherein the contact plug is in physical contact with the dielectric layer. In an embodiment, the method comprises depositing a first tungsten layer; depositing a second tungsten layer over the first tungsten layer; and depositing a third tungsten layer over the second tungsten layer, wherein the first tungsten layer, the second tungsten layer, and the third tungsten layer are deposited using different deposition methods. In an embodiment, the forming the contact plug comprises depositing a first tungsten layer; performing a treatment process on the first tungsten layer using a process gas comprising hydrogen (H₂); and depositing a second tungsten layer over the first tungsten layer.

In accordance with some embodiments, a structure comprises a semiconductor region; a transistor comprising a gate stack on the semiconductor region; and a source/drain region adjacent to the gate stack; a dielectric layer over the gate stack and the source/drain region; and a tungsten-containing conductive layer comprising a lower part in the dielectric layer, wherein the lower part is over and contacting the gate stack, and wherein the lower part has a first grain size; and an upper part over the dielectric layer and joined to the lower part, wherein the upper part laterally extends beyond edges of the lower part, and wherein the upper part has a second grain size greater than the first grain size. In an embodiment, entireties of the upper part and the lower part are formed of tungsten, and wherein the tungsten-containing conductive layer comprises a plurality of tungsten layers. In an embodiment, the first grain size is in a first range between about 10 Å and about 1,000 Å, and the second grain size is in a second range between about 30 Å and about 2,000 Å.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a dielectric layer over a conductive feature;
etching the dielectric layer to form an opening, wherein the conductive feature is overlapped by the opening;
forming a tungsten layer to fill the opening, wherein the forming the tungsten layer comprises a plurality of deposition processes to form a plurality of sub-layers, and wherein the plurality of deposition processes are different from each other; and
planarizing the tungsten layer, wherein a portion of the tungsten layer in the opening forms a contact plug that is electrically coupled to the conductive feature.

2. The method of claim 1, wherein the forming the tungsten layer comprises:
depositing a tungsten liner; and
depositing a tungsten nucleation layer over the tungsten liner.

3. The method of claim 2, wherein the tungsten liner and the tungsten nucleation layer are deposited using different deposition methods.

4. The method of claim 3, wherein the tungsten liner is deposited using physical vapor deposition, and wherein the tungsten nucleation layer is deposited using atomic layer deposition or chemical vapor deposition.

5. The method of claim 2, wherein the plurality of deposition processes further comprises depositing a bulk tungsten layer over the tungsten nucleation layer.

6. The method of claim 1, wherein the contact plug comprises a source/drain contact plug.

7. The method of claim 1, wherein the contact plug comprises a gate contact plug.

8. The method of claim 1, wherein the plurality of sub-layers have different compositions.

9. A method comprising:
forming a transistor comprising:
forming a gate stack over a semiconductor region; and
forming a source/drain region aside of the gate stack; and
forming a contact plug in a contact opening, wherein the contact opening comprises a source/drain contact opening over the source/drain region or a gate contact opening over the gate stack, and wherein the forming the contact plug comprises:
depositing a first tungsten-containing layer; and
depositing second tungsten-containing layer over the first tungsten-containing layer, wherein the first tungsten-containing layer and the second tungsten-containing layer have different compositions.

10. The method of claim 9, wherein both of the first tungsten-containing layer and the second tungsten-containing layer comprise elemental tungsten.

11. The method of claim 9, wherein:
the first tungsten-containing layer comprises a tungsten liner that is in contact with dielectric materials in which the contact opening is formed; and
the second tungsten-containing layer comprises a bulk tungsten layer that fully fills the contact opening.

12. The method of claim 11 further comprising depositing a nucleation layer over the tungsten liner, wherein the bulk tungsten layer is deposited over the nucleation layer.

13. The method of claim 12, wherein the nucleation layer has a different composition than the tungsten liner, and a same composition as the bulk tungsten layer.

14. The method of claim 12, wherein the tungsten liner is free from chlorine, and the bulk tungsten layer comprises chlorine.

15. The method of claim 9, wherein the first tungsten-containing layer and the second tungsten-containing layer are deposited using different precursors.

16. The method of claim 9, wherein the first tungsten-containing layer and the second tungsten-containing layer are formed using different methods.

17. A method comprising:
forming a transistor comprising:
forming a source/drain region in a semiconductor region; and
forming a gate stack adjacent to the gate stack;
forming a dielectric layer over the source/drain region and the gate stack, wherein the dielectric layer has an opening therein; and
performing a plurality of deposition processes to form a tungsten layer that is electrically connected to at least one of the source/drain region and the gate stack, the plurality of deposition processes comprising:
a first deposition process to deposit a tungsten liner;
a second deposition process to deposit a tungsten nucleation layer over the tungsten liner; and
a third deposition process to deposit a bulk tungsten layer over the tungsten nucleation layer.

18. The method of claim 17, wherein process conditions of the first deposition process, the second deposition process, and the third deposition process are different from each other.

19. The method of claim 18, wherein a transition process from the second deposition process to the third deposition process comprises increasing a wafer temperature, and maintaining precursor flow rates and chamber pressure unchanged.

20. The method of claim 17, wherein the tungsten liner, the tungsten nucleation layer, and the bulk tungsten layer comprise elemental tungsten.
